(19) United States
(12) Patent Application Publication
(10) Pub. No.: US 2013/0256755 A1
(43) Pub. Date: Oct. 3, 2013

(54) SEMICONDUCTOR DEVICE AND METHOD FOR MANUFACTURING THE SAME

(71) Applicant: SUMITOMO ELECTRIC DEVICE INNOVATIONS, INC., Yokohama-shi (JP)

(72) Inventor: Shunsuke Kurachi, Yokohama-shi (JP)

(73) Assignee: SUMITOMO ELECTRIC DEVICE INNOVATIONS, INC., Yokohama-shi (JP)

(21) Appl. No.: 13/850,522

(22) Filed: Mar. 26, 2013

(30) Foreign Application Priority Data
Mar. 28, 2012 (JP) 2012-074400

(51) Int. Cl. H01L 29/778; H01L 29/66

(52) U.S. Cl. CPC H01L 29/778; H01L 29/66431
USPC 257/194; 438/172

(57) ABSTRACT

A semiconductor device includes: a gate electrode that is provided on a semiconductor layer, and contains a Ni-containing layer; an insulating film that covers the gate electrode, and has a step; a covering layer that is provided between the gate electrode and the insulating film, and is arty one of a metal which has a melting point equal to or more than 1,600 degrees, and an oxide and a nitride of the metal; and a metal layer that is provided on the step.

### CROSS-REFERENCE TO RELATED APPLICATION

This application is based upon and claims the benefit of priority of the prior Japanese Patent Application No. 2012-074400, filed on Mar. 28, 2012, the entire contents of which are incorporated herein by reference.

### BACKGROUND

(i) Technical Field

certain aspect of the embodiments discussed herein is rerated to a semiconductor device and a method for manufacturing the same.

(ii) Related Art

A semiconductor device using a nitride semiconductor is used for a power device or the like which operates at high frequency and high output. Especially, there is known a PET (Field Effect Transistor) such as a HEMT (High Electron Mobility Transistor), as a semiconductor device suitable for amplification in a high frequency band, such as a microwave, a submillimeter wave, and a millimeter wave.

In the semiconductor device using the nitride semiconductor, a silicon nitride film is formed on a nitride semiconductor layer as a protective film. A collapse phenomenon of a drain current can be reduced by using the nitride silicon film as the protective film. Japanese Patent Application Publication No. 2006-261252 discloses using the nitride silicon film which limited composition in order to improve adhesion of the nitride semi conductor layer and the silicon nitride film.

In an example of the semiconductor device using the nitride semiconductor, an insulating film is formed so as to cover a gats electrode formed on the nitride semiconductor film. On the insulating film, a metal layer such as a field plate is formed. When such a FET is energized, Ni (nickel) contained in the gate electrode diffuses inside the insulating film toward the metal layer. As a result, the gate electrode and the metal layer short-circuit, and the FET may break down.

It is an object of the present invention to provide a semiconductor device and a method for manufacturing the same that can restrain energization defect.

According to an aspect of the present invention, there is provided a semiconductor device including; a gate electrode that is provided on a semiconductor layer, and contains a Ni-containing layer; an insulating film that covers the gate electrode, and has a step; a covering layer that is provided between the gate electrode and the insulating film, and is any one of a metal which has a melting point equal to or more than 1,600 degrees, and an oxide and a nitride of the metal; and a metal layer that is provided on the step.

### BRIEF DESCRIPTION OF THE DRAWINGS

FIG. 1 is a cross-sectional diagram illustrating an example of a semiconductor device according to a comparative example 1;

FIG. 2 is a cross-sectional diagram illustrating an example of a semiconductor device according to a first embodiment;

FIGS. 3A to 3C are cross-sectional diagrams illustrating an example of a method for manufacturing the semiconductor device according to the first embodiment (Part 1);

FIGS. 4A to 4C are cross-sectional diagrams illustrating an example of the method for manufacturing the semiconductor device according to the first embodiment. (Part 2);

FIG. 5A is a cross-sectional diagram illustrating an example of a semiconductor device according to a first variation of the first embodiment; and

FIG. 5B is a cross-sectional diagram illustrating an example of a semiconductor device according to a second variation of the first embodiment.

### DETAILED DESCRIPTION

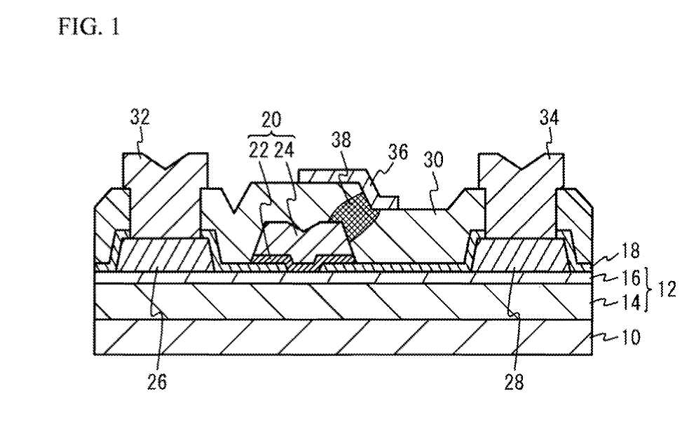

First, a description will be given of a comparative example 1 of an FET using a nitride semiconductor. FIG. 1 is a cross-sectional diagram illustrating an example of a semiconductor device according to the comparative example 1. On a substrate 10 which is a SiC substrate, a channel layer 14 which is a GaN layer and an electron supply layer 16 which is an AlGaN layer are provided in this order as a nitride semiconductor layer 12, as illustrated in FIG. 1. Here, a barrier layer which is an AlN layer may be provided between the substrate 10 and the channel layer 14. On the electron supply layer 16, a cap layer which is a GaN layer may he provided.

On the nitride send conductor layer 12, a first insulating film 18 which is a nitride silicon film is provided, for example. An opening is formed, on the first insulating film 18. A gate electrode 20 is provided on the nitride semiconductor layer 12 so as to be embedded at the opening. The gate electrode 20 is a metal layer in which a Ni film 22 and an Au film 24 are stacked from a side of the nitride semiconductor layer 12 in this order. That is, the gate electrode 20 has a Ni-containing layer. The gate electrode 20 is a T-type gate electrode having a T-shape, and is bonded to the nitride semiconductor layer 12 by Schottky junction.

A source electrode 26 and a drain electrode 28 are provided on the nitride semiconductor layer 12 so as to sandwich the gate electrode 20. The source electrode 26 and the drain electrode 28 are metal films in which a Ti film and an Al film are stacked from a side of the nitride semiconductor layer 12 in this order, for example. The source electrode 26 and the drain electrode 28 are bonded to the nitride semiconductor layer 12 by Ohmic junction.

A second insulating film 30 which is a nitride silicon film is provided on the first insulating film 18 so as to cover the gate electrode 20. The second insulating film 30 has a step which has reflected the shape of a step of the gate electrode 20. Each of the first insulating film 18 and the second insulating film 30 has a function which protects the nitride semiconductor layer 12. The second insulating film 30 is formed so as to contact an upper surface and side surfaces of the gate electrode 20. A source wiring 32 and a drain wiring 34 are formed on the source electrode 26 and the drain electrode 23 through the second insulating film 30 and the first insulating film 13. The source wiring 32 is provided so as to contact an upper surface of the source electrode 26, for example. The drain wiring 34 is provided so as to contact an upper surface of the drain electrode 28, for example. The source wiring 32 and the drain wiring 34 are metal layers such as an Au plating layer.

By being connected to the source wiring 32 outside an active region of the FET, a field plate 36 electrically connected to the source electrode 20 is provided on the second insulating film 30. The field plate 36 is provided at a position where the step of the second insulating film 30 between the gate electrode 20 and the drain electrode 28 is covered. The field plate 30 extends along the gate electrode 20 and to a portion located above the gate electrode 20. The field plate 30 is a metal layer such as an Ac plating layer.

An inventor has per foiled a high temperature energization, test to the FET of the comparative example 1. The high temperature energization test has been performed by controlling a negative voltage to be applied to the gate electrode 20 so that a drain-source current becomes a given value. In the FET after the high temperature energization test, a phenomenon in which Ni (nickel) contained in the gate electrode 20 diffuses toward the field plate 30 having the same electrical potential as the source electrode 26 which is a ground potential has occurred. This is considered that Ni contained in the gate electrode 20 has reacted with oxygen in moisture adsorbed to the gate electrode 20 to become ionised nickel oxide, and the ionised nickel oxide has diffused toward the field plate 36 by the heat and an electric field of the high temperature energization test. In FIG. 1, a code 38 illustrates a region where Ni has diffused.

Thus, Ni contained in the gate electrode 20 diffuses inside the second insulating film 30 toward the field plate 36, so that the gate electrode 20 and the field plate 36 short-circuit, and the semiconductor device may break down. Therefore, an embodiment that can restrain such energization defect is described below.

(First Embodiment)

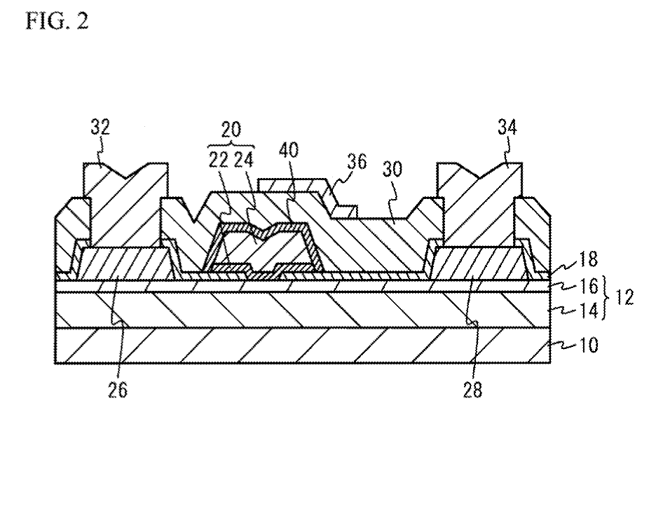

FIG. 2 is a cross-sectional diagram illustrating an example of a semiconductor device according to a first embodiment. FIG. 2 is different from FIG. 1 of the comparative example 1 in that a covering layer 40 is provided. Since other configuration of FIG. 2 is the same as that of FIG. 1, the covering layer 40 is explained later and description of other configuration is omitted.

The covering layer 40 is provided so as to cover the upper surface and the side surfaces of the Au film 24 and the side surfaces of the Ni film 22. The covering layer 40 is made of a conductive metal, and is a metal having a melting-point equal to or more than 1,600 degrees (hereinafter referred to as “a high melting point metal”). The metal having the melting point equal to or more than 1600 degrees can restrain diffusion of Ni effectively. An example of the high melting point metal may be any one of Ti, Cr, Mo, Ta, W and Hf. The covering layer 40 may be the high melting point-metal composed of a single layer or lamination layers. Therefore, the covering layer 40 can contain at least one of a Ti film, a Cr film, a Mo film, a Ta film, a W film and a Hf film.

In addition, an oxide or a nitride of the high melting point metal can be used as the covering layer 40. The oxide or the nitride of the high melting point metal may be composed of a single layer or lamination layers. Therefore, the covering layer 40 can also contain at least one of a Ti oxide film, a Cr oxide film, a Mo oxide film, a Ta oxide film, a W oxide film, a Hf oxide film, a Ti nitride film, a Cr nitride film, a Mo nitride film, a Ta nitride film, a W nitride film and a Hf nitride film. The oxide or the nitride of the high melting point metal can obtain more compactness, compared with the high melting point metal. Thereby, the diffusion of Ni contained in the gate electrode 20 can be restrained more effectively.

The second insulating film 30 is provided so as to cover the covering layer 40, e.g. so as to contact the upper surface and the side surfaces of the covering layer 40. Thus, by the existence of the covering layer 40, the second insulating film 30 is provided without contacting the Mi film 22 and the Au film 24. That is, the covering layer 40 covers the Ni film 22 and the Au film 24 without exposing them so that the second insulating film 30 does not contact the Ni film 22 and the An film 24.

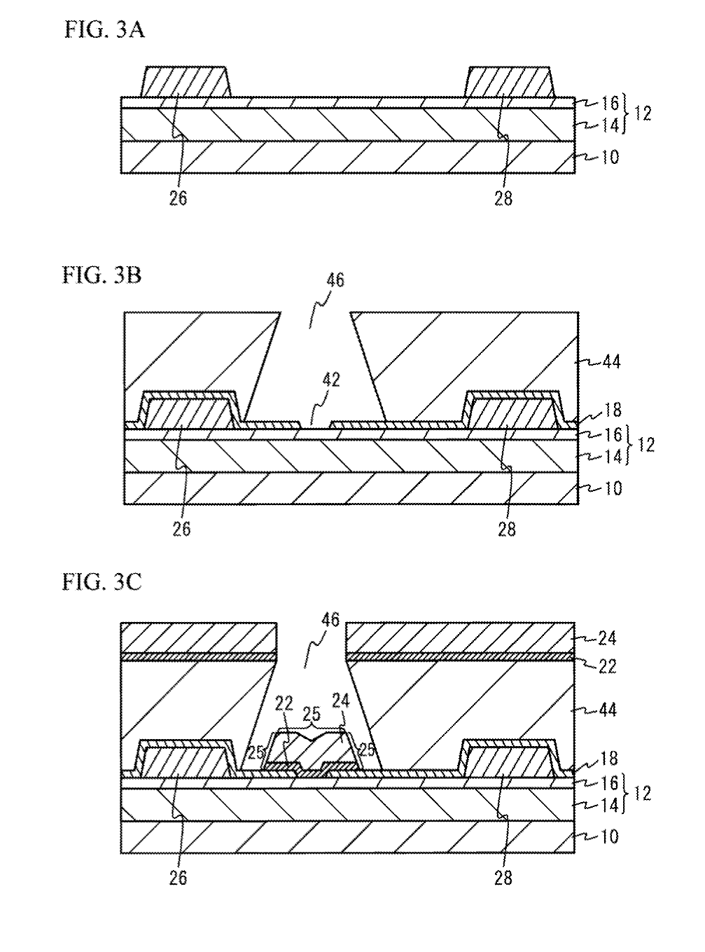

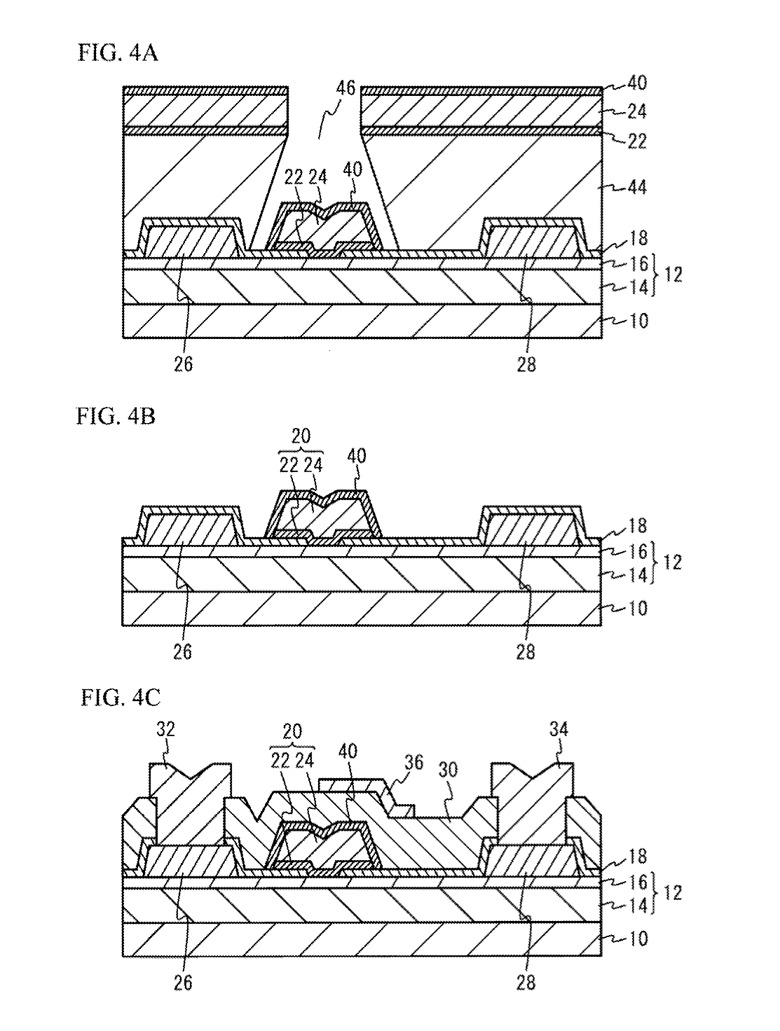

Next, a description will be given of a method for manufacturing the semiconductor device according to the first embodiment. FIGS. 3A to 3C and 4A to 4C are cross-sectional diagrams illustrating an example of the method for manufacturing the semiconductor device according to the first embodiment. On the substrate 10, the channel layer 14 which is the GaN layer and the electron supply layer 16 which is the AlGaN layer are provided in this order as the nitride semiconductor layer 12, as illustrated in FIG. 3A. The channel layer 14 and the electron supply layer 16 can be formed with the use of a MOCVD (Metal Organic Chemical vapor Deposition) method. On the nitride semiconductor layer 12, a metal film in which the Ti film and the Al film are stacked from the side of the nitride semiconductor layer 12 in this order is formed with the use of a vacuum deposition method or a lift-off method. Then, the metal film is annealed at the temperature of 500 to 800 degrees, for example. The source electrode 26 and the drain electrode 23 which are Ohmic electrodes bonded to the nitride semiconductor layer 12 by Ohmic junction are formed.

On the nitride semiconductor layer 12, the first insulating film 18 which is the silicon nitride film, for example, is formed with the use of a plasma CVD (Plasma-enhanced Chemical Vapor Deposition) method so as to cover the source electrode 26 and the drain electrode 28, as illustrated in FIG. 3B. A part of the first insulating film 13 corresponding to a region where the gate electrode should foe formed is removed, and hence the opening should foe formed is removed, and hence an opening 42 is formed between the source electrode 26 and the drain electrode 28. On a bottom surface of the opening 42, the electron supply layer 16 is exposed. A resist layer 44 which is a photoresist is applied on the first insulating film 18. Exposure and development are performed to the resist layer 44, and an opening 46 which is an inverse tapered shape is formed at a position corresponding to the opening 42 of the first insulating film 18.

On the resist layer 44 and the electron supply layer 16 in the opening 46 of the resist layer 44, the Ni film 22 and the Au film 24 are formed in this order with the use of the vacuum deposition, method, as illustrated in FIG. 3C. The film thickness of the Ni film 22 is 100 nm, for example. The film thickness of the Au film 24 is 400 nm, for example. Thereby, the metal film in which the Ni film 22 and the Au film 24 are stacked from the side of the nitride semiconductor layer 12 in this order is formed at the opening 42 of the first insulating film 18. Each of the Ni film 22 and the An film 24 is a material layer of the gate electrode having the Ni-containing layer.

As illustrated in FIG. 4A, the covering layer 40 is formed so as to cover the Au film 24 and exposed surfaces 25 of the Ni film 22 and the Au film 24 formed in the opening 46 of the resist layer 44, using a sputtering method, as illustrated in FIG. 4A. That is, the respective exposed surfaces 25 of the Ni film 22 and the Au film 24 in FIG. 3G are covered with the covering layer 40. The covering layer 40 is formed so as to perfectly cover the Ni film 22 and the Au film 24 without exposing them. Here, when the covering layer 40 is formed using the resist layer 44 used for forming the Ni film 22 and the Au film 24 for process simplification, it is necessary to take into consideration wrap-around of the covering layer 40 to a portion which becomes a shadow of the resist layer 44. From this, it is effective to form the covering layer 40 using the sputtering method, without directly using the vacuum evaporation method used for formation with the Ni film 22 and the Au film 24. This is because there is much wrap-around of the covering layer 40 when the sputtering method is used, compared with the case where the vacuum deposition method is used.

Here, after the Ni film 22 and the Au film 24 are formed, the resist layer 44 is removed, the covering layer 40 is formed on the whole area of the nitride semiconductor layer 12 by the sputtering method, and then the covering layer 40 corresponding to a region other than the gate electrode is removed with the use of a new resist layer. Thereby, the covering layer 40 can be also formed. In this case, the covering layer 40 can be also formed with the use of the vacuum deposition method.

Moreover, all of the Ni film 22, the Au film 24, and the covering layer 40 can be also formed with the use of the sputtering method. In this case, since the Ni film 22, the Au film 24, and the covering layer 40 are easily formed also on an inner wall of the opening 46 of the resist layer 44, the proper thicknesses of the Ni film 22, the Au film 24, and the covering layer 40 are required. This is because it is difficult to remove the subsequent resist layer 44 when these materials are thickly formed as a film on the inner wail of the opening 46 of the resist layer 44.

Next, a detailed description will be given of formation of the covering layer 40. When the covering layer 40 is made of the high melting point metal, sputtering of the high melting point metal is performed at a low deposition rate. It is desirable that the deposition rate is 50 or less nm/min, and it is more desirable that the deposition rate is 20 or less nm/min. Thereby, after the high melting point metal particles having large kinetic energy adhere to the upper surface of the Au film 24, time required for high melting point metal particles to cover from the upper surface of the Au film 24 to the side of the An film 24 and the side of the Ni film 22 can be gained. Therefore, the covering layer 40 can cover the Ni film 22 and the Au film 24 without exposing them. As sputtering conditions for the high melting point metal, the following conditions are mentioned, for example. Ar gas flows by 40 to 60 sccm. Under the gas pressure of 10 to 75 mTorr, when the high melting point metal is Ti, a DC electric power is set to 300 to 700 W. When the high melting point metal is Cr, the DC electric power is set to 300 to 900 W. When the high melting point metal is Mo or Hf, the DC electric power is set to 300 to 1000 W. When the high melting point metal is Ta or W, the DC electric power is set to 500 to 1200 m.

When the covering layer 40 is made of the oxide or the nitride of the high melting point metal, any one of the following two methods can be used. A first method is to form the covering layer 40 composed of the oxide or nitride of the high melting point metal at the low deposition rate using a reactive sputtering method. Also in this case, the covering layer 40 can cover the hi film 22 and the Au film 24 without exposing them by making the deposition rate of the sputtering low. As sputtering conditions at the time of using the reactive sputtering method, the following conditions are mentioned, for example. When the covering layer 40 is the Ti oxide, for example, at the time of deposition, gas flow ratio is set to “O₂:Ar=5 to 15 sccm:35 to 45 sccm”, the pressure is set to 10 to 75 mTorr, and the DC electric power is set to 300 to 700 W. When the covering layer 40 is the Ti nitride, for example, at the time of deposition, gas flow ratio is set to “N₂: Ar=10 to 30 sccm: 30 to 50 sccm”, the pressure is set to 10 to 75 mTorr, and the DC electric power is set to 300 to 700 W.

A second method is to form the covering layer 40 composed of the oxide or nitride of the high melting point metal by sputtering the high melting point metal at the low deposition rate, and then performing oxygen plasma treatment or nitrogen plasma treatment on the high melting point metal. In the oxygen plasma treatment or the nitrogen plasma treatment, the high melting point metal may be processed without taking out from a sputtering device, i.e., without exposing to air. Alternatively, the high melting point metal may be processed with another device after if is taken out from the sputtering device and is exposed to air. When the high melting point metal is processed with another device, the high melting point metal may be processed after the resist layer 44 is removed by the lift-off method or before the resist layer 44 is removed. As conditions of the oxygen plasma treatment and the nitrogen plasma treatment, the following conditions are mentioned, for example. In the oxygen plasma treatment and the nitrogen plasma, treatment, at the time of plasma treatment, the pressure is set to 1.0 Torr, the DC electric power is set to 200 W, and the treatment time is set to 5 minutes.

As illustrated in FIG. 4B, the resist layer 44 is removed by the lift-off method. Thereby, the Ni film 22, the Au film 24, and the covering layer 40 formed on the resist layer 44 are removed, and the gate electrode 20 containing the Ni film 22 and the Au film 24 is formed on the nitride semiconductor layer 12.

As illustrated in FIG. 4C, the second insulating film 30 which is the silicon nitride film, for example, is formed with the use of the plasma CVD method so as to cover the covering layer 40. The second insulating film 30 has the step which has reflected the shape of the step of the gate electrode 20. The second insulating film 30 is formed so as to contact an upper surface and side surfaces of the covering layer 40. The second insulating film 30 and the first insulating film 18 on the source electrode 26 and the drain electrode 28 are removed, so that openings are formed. A metal layer is formed in the openings and on the second insulating film 30 with the use of a plating method. The metal layer contains: the source wiring 32 that contacts the upper surface of the source electrode 26; the drain wiring 34 that contacts the upper surface ox the drain electrode 28; and the field plate 36 provided at a position where the step of the second insulating film 30 is covered.

In the FET according to the first embodiment, the covering layer 40 is provided between the Ni film 22 (i.e., Ni-containing layer) contained in the gate electrode 20 and the second insulating film 30, as illustrated in FIG. 2. When the FET according to the first embodiment is energized, Ni contained in the gats electrode 20 easily diffuses toward the second insulating film 30 from the Ni film 22. Therefore, the covering layer 40 is provided between the Ni film 22 and the second insulating film 30, so that it is possible to restrain Ni contained in the gate electrode 20 from, being diffused toward the second insulating film 30, Therefore, according to the first embodiment, it is possible to restrain energization detect of the FET.

From a viewpoint of restraining diffusion of Ni contained in the gate electrode 20, it is desirable that the covering layer 40 is provided between the Ni film 22 and the second insulating film 30 so as to completely cover the Ni film 22 without exposing it. It is more desirable that the covering layer 40 is provided so as to completely cover the Ni film 22 and the Au film 24 without exposing them, and the Ni film 22 and the Au film 24 do not contact the second insulating film 30 by the covering layer 40.

The FET according to the first embodiment has the following manufacturing processes, and is manufactored. That is, the resist layer 44 having the opening 46 whose inner wall has the inverse tapered shape is formed on the nitride semiconductor layer 12 (see FIG. 3B). The material layer (i.e., the Ni film 22 and the Au film 24) of the gate electrode having the Ni-containing layer is deposited on the resist layer 44 and on the nitride semiconductor layer 12 in the opening 46 of the resist layer 44 (see FIG. 3C). Then, the covering layer 40 is deposited on the material layer and so as to cover an exposed surface of the Ni-containing layer (i.e., the Ni film 22) in the gate electrode, by the sputtering method (see FIG. 4A). Then, the resist layer 44 is removed, so that the Ni film 22, the Au film 24, and the covering layer 40 on the resist layer 44 are removed (see FIG. 4B). The second insulating film 30 having the step which has reflected the shape of the step of the gate electrode 20 is formed on the covering layer 40, and the field plate 36 is formed at a position where the step of the second insulating film 30 is covered (see FIG, 4C).

As described in FIG. 2, it is desirable that the second insulating film 30 is formed so as to contact the upper surface and the side surfaces of the covering layer 40. When the second insulating film 30 is formed so as to contact the upper surface and the side surfaces of the gate electrode 20 as illustrated in FIG. 1 of the comparative example 1, there is a possibility that film peeling may arise from degradation of the adhesion between the Au film 24 and the second insulating film 30. However, when the second insulating film 30 is formed so as to contact the upper surface and the side surfaces of the covering layer 40, since the covering layer 40 is the high melting point metal, such as Ti and Cr, or the oxide or the nitride of the high melting point metal, the adhesion between the covering layer 40 and the second insulating film 30 can be improved. Therefore, the film peeling can be restrained.

When the thickness of the covering layer 40 is thin, an effect for restraining diffusion of Ni contained in the gate electrode 20 reduces, and hence it is desirable that the thickness of the covering layer 40 is equal to or more than 10 nm. On the other hand, when the thickness of the covering layer 40 is thick, the processability at the time of forming a via-hall in the second insulating film 30 in order to form a through-electrode to be connected to the gate electrode 20 deteriorates, and hence it is desirable that the thickness of the covering layer 40 is equal to or less than 100 nm. Therefore, it is desirable that the thickness of the covering layer 40 is equal to or more than 10 nm and equal to or less than 100 nm. It is more desirable that the thickness of the covering layer 40 is equal to or more than 20 nm and equal to or less than 90 nm. It is further more desirable that the thickness of the covering layer 40 is equal to or more than 30 nm and equal to or less than 80 nm.

As illustrated in FIGS. 4A and 4B, the shapes (i.e., patterns) of the gate electrode 20 and the covering layer 40 are decided by the shape of the opening 46 of the resist layer 44. The shape of the opening 46 of the resist layer 44 includes not only the shape of the gate electrode 20 but also a shape of an electrode pad (not shown) extended and connected from the gate electrode 20. That is, the opening 46 of the resist layer 44 may include the shapes (i.e., patterns) of the gate electrode 20 and the electrode pad connected to the gate electrode 20. In this case, not only the gate electrode 20 and the covering layer 40 but also the electrode pad and the covering layer 40 covering the electrode pad are formed in the opening 46 of the resist layer 44. At this time, it is desirable that the covering layer 40 is made of materials with electrical conductivity. This is because when the covering layer 40 has electrical conductivity, even if the covering layer 40 constitutes a part of the electrode pad, it is possible to restrain loss of the electrical conductivity of the electrode pad.

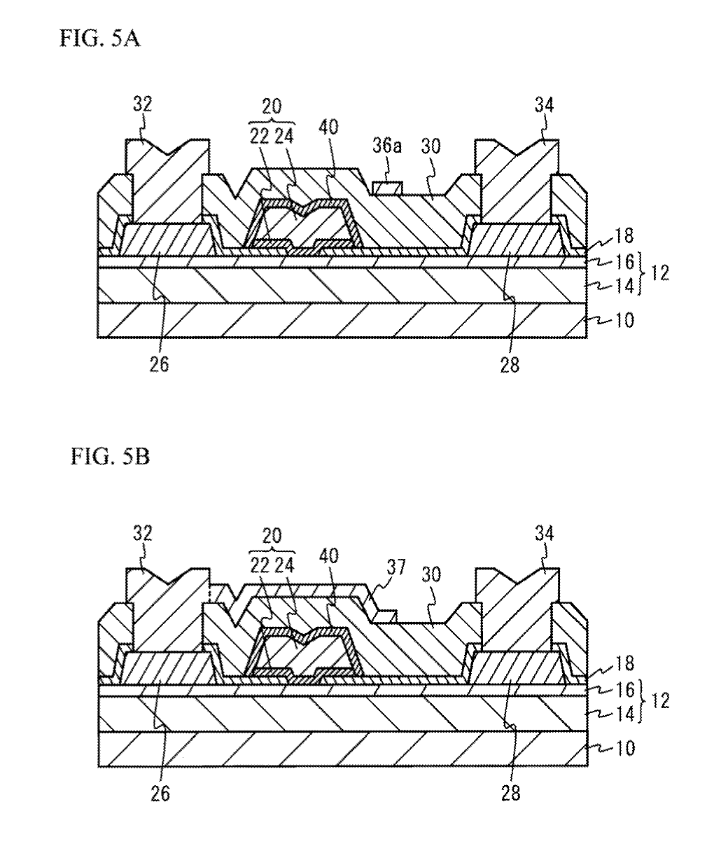

The description has been given of a case where the field plate 36 is provided at the position where the step of the second insulating film 30 is covered, and the field plate 36 extends along the gate electrode 20 and to a portion located above the gate electrode 20. However, like the FET according to a first variation of the first embodiment of FIG. 5A, a field plate 36a may be located between the gate electrode 20 and the drain electrode 28 and may not extend to a portion located above the gate electrode 20. As is the case with the field, plate 36, the field plate 36a is also made of the metal layer such as the Au plating layer, and is connected to the source wiring 32 outside the active region of the FET.

Like the FET according to a second variation of the first embodiment of FIG. 5B, a source wall 37 may be provided instead of the field plate 36. The source wall 37 is made of the metal layer such as the Au plating layer, is connected to the source wiring 32, and extends from the source wiring 32 to the position where the step of the second insulating film 30 is covered, so as to cover the gate electrode 20 via the second insulating film 30.

The present embodiment is not limited to the case where the field plates 36 and 36a and the source wall 37 which are metal layers formed on the second insulating film 30 are electrically Connected to the source electrode 26, The field plates 36 and 36a and the source wail 37 may not he electrically connected to the source electrode 26. Each of the field plates 36 and 36a and the source wail 37 may be a lifted electrical conductor. However, when each of the field plates 36 and 36a and the source wall 37 is electrically connected to the source electrode 26, Ni contained in the gate electrode 20 easily diffuses toward each of the field plates 36 and 36a and the source wall 37, as described in the comparative example 1. Therefore, when each of the field plates 36 and 36a. and the source wall 37 is electrically connected to the source electrode 26, it is effective to form the covering layer 40.

A Si board, a sapphire board, or a GaN board other than the SIC board can be used as the substrate 10, for example. A single layer or lamination layers which contains at least one of a GaN layer, an InN layer, an AlN layer, an InGaN layer, an AlGaN layer, an InAlN layer and an InAlGaN layer can be used as the nitride semiconductor layer to be formed on the substrate 10. Moreover, a semiconductor layer other than the nitride semiconductor layer, e.g. a GaAs-based semiconductor layer may be provided on the substrate 10. The GaAs-based semiconductor layer may be a GaAs layer, an AlGaAs layer, an InGaAs layer or the like. An insulating film other than the silicon nitride film may be used as the first insulating film 18 and the second insulating film 30. A barrier metal film, such as a Ti film or a Mo film, may be provided between the Ni film 22 and the Au film 24 as the gate electrode 20.

Although the embodiments of the present invention is described in detail, the present invention is not limited to the specifically described embodiments and variations but other embodiments and variations may be made without departing from the scope of the claimed invention.

What is claimed is:

1. A semiconductor device comprising:
a gate electrode that is provided on a semiconductor layer, and contains a Mi-containing layer;
an insulating film that covers the gate electrode, and has a step;
a covering layer that is provided between the gate electrode and the insulating film, and is any one of a metal which has a melting point equal to or more than 1,600 degrees, and an oxide and a nitride of the metal; and
a metal layer that is provided on the step.

2. The semiconductor device according to claim 1, wherein the metal is any one of Ti, Cr, Mo, Ta, W and Hf.

3. The semiconductor device according to claim 1, wherein the metal layer is any one of a field plate provided along the gate electrode and a source wall provided so as to cover the gate electrode.

4. The semiconductor device according to claim 1, wherein the thickness of the covering layer is equal to or more than 10 nm and equal to or less than 100 nm.

5. The semiconductor device according to claim 1, wherein the insulating film is in contact with an upper surface and side surfaces of the covering layer.

6. The semiconductor device according to claim 1, wherein the gate electrode has an Au layer provided on the Ni-containing layer.

7. The semiconductor device according to claim 6, wherein the gate electrode has a layer containing one of Ti or Mo provided between the Ni-containing layer and the Au layer.

8. The semiconductor device according to claim 1, wherein the step of the insulating film has a upper edge and a lower edge, and the metal layer is provided on the lower edge of the step.

9. A method for manufacturing a semiconductor device, comprising:
forming a resist layer on a semiconductor layer, the resist layer having an opening whose inner wail has an inverse tapered, shape;
depositing a material layer of a gate electrode having a Ni-containing layer on the resist layer and on the semiconductor layer in the opening;
depositing a covering layer on the material layer by a sputtering method, the covering layer being any one of a metal which has a melting point equal to or more than 1,600 degrees, and an oxide and a nitride of the metal;
removing the resist layer to remove the material layer and the covering layer on the resist layer;
forming an insulating film having a step; and
forming a metal layer on the insulating film.

10. The method for manufacturing the semiconductor device according to claim 9, wherein the metal is any one of Ti, Cr, Mo, Ta, W and Ni.

11. The method for manufacturing the semiconductor device according to claim 9, wherein the metal layer is any one of a field, plate provided along the gate electrode and a source wail provided so as to cover the gate electrode.

12. The method for manufacturing the semiconductor device according to claim 9, wherein the opening of the resist, layer includes patterns of the gate electrode and a electrode pad to be connected to the gate electrode, and the covering layer has electrical conductivity.

13. The method for manufacturing the semiconductor device according to claim 9, wherein the gate electrode has an Au layer provided on the Ni-containing layer.

14. The method for manufacturing the semiconductor device according to claim 13, wherein the gate electrode has a layer containing one of Ti or Mo provided between the Ni-containing layer and the Au layer.

15. The method for manufacturing the semiconductor device according to claim 9, wherein the step of the insulating film has a upper edge and a lower edge, and the metal layer is provided on the lower edge of the step.

16. A semiconductor device comprising:
a Ni-containing layer;
an insulating film that covers the Ni-containing layer, and has a step having an upper edge and a lower edge;
a covering layer that is provided between the Ni-containing layer and the insulating film, and is any one of a metal which has a melting point equal to or more than 1,600 degrees, and an oxide and a nitride of the metal; and
a metal layer that is provided on the lower edge of the step in the insulating layer.

17. The semiconductor device according to claim 16, wherein an Au layer is provided on the Ni-containing layer.

18. The semiconductor device according to claim 17, wherein Ti or Mo is provided between the Ni-containing layer and the Au layer.
